(19) United States
(12) Patent Application Publication
(10) Pub. No.: US 2026/0026414 A1
(43) Pub. Date: Jan. 22, 2026

(54) FAN-OUT WAFER LEVEL PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/254,011

(22) Filed: Jun. 30, 2025

(30) Foreign Application Priority Data
Jul. 19, 2024 (TW) 113127136

(51) Int. Cl. H01L 23/498; H01L 21/48; H01L 23/00; H01L 23/15; H01L 23/538; H01L 25/18; H05K 1/18

(52) U.S. Cl. CPC H01L 23/49811; H01L 21/4853; H01L 23/15; H01L 23/49838; H01L 23/49866; H01L 23/5386; H01L 24/19; H01L 24/20; H01L 24/24; H01L 24/32; H01L 24/73; H01L 25/18; H01L 2224/19; H01L 2224/215; H01L 2224/24225; H01L 2224/32225; H01L 2224/73267; H05K 1/181

(57) ABSTRACT

A fan-out wafer level packaging (FOWLP) unit which includes a substrate, at least one die, a first dielectric layer, at least one conductive pillar, a second dielectric layer, a plurality of first conductive circuits, a first outer protective layer, a third dielectric layer, a plurality of second conductive circuits, and a second outer protective layer is provided. The die is electrically connected with the outside through at least one first bonding pad around a chip area on a second surface of the die. The die is further electrically connected with the outside through a second bonding pad in at least one opening of the second outer protective layer. Both the first conductive circuits and the second conductive circuits are produced by filling a metal paste into slots and grinding the metal paste. Thereby problems of conventional FOWLP technology including higher manufacturing cost and less environmental benefit can be solved.

### CROSS-REFERENCE TO RELATED APPLICATIONS

This non-provisional application claims priority under 35 U.S.C. § 119(a) on Patent Application No(s). 113127136 filed in Taiwan, R.O.C. on Jul. 19, 2024, the entire contents of which are hereby incorporated by reference.

### BACKGROUND OF THE INVENTION

The present invention relates to a packaging unit, especially to a fan-out wafer level packaging (FOWLP) unit.

Packaging technology with features of compact design, high efficiency, and high reliability is a trend in semiconductor industry. In the semiconductor packaging, Fan-Out Wafer Level Packaging (FOWLP) is a packaging technology available now.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree, the most critical point is the manufacturing of the respective conductive circuits in the RDL. However, the formation of the respective conductive circuits in the RDL of the FOWLP technology available now is by chemical plating or electroplating. Thus not only cost for material and manufacturing is high, the manufacturing process is also not environmental friendly.

Moreover, in order to meet requirements for compact design and light weight of electronic products, there is a need to allow dies in the FOWLP unit to be electrically connected to the outside through two opposite surfaces of a packaging unit, without increasing a thickness of the whole unit.

### SUMMARY OF THE INVENTION

Therefore, it is a primary object of the present invention to provide a FOWLP unit which includes a substrate, at least one die, a first dielectric layer, at least one conductive pillar, a second dielectric layer, a plurality of first conductive circuits, a first outer protective layer, a third dielectric layer, a plurality of second conductive circuits, and a second outer protective layer. The die is electrically connected with the outside through at least one first bonding pad around a chip area on a second surface of the die. The die can also be electrically connected with the outside through a second bonding pad in at least one opening of the second outer protective layer. The first conductive circuits and the second conductive circuits are produced by filling a metal paste into slots and grinding the metal paste. Thereby problems of the FOWLP technology available now generated during manufacturing of the respective conductive circuits including higher manufacturing cost and less environmental benefit can be solved.

In order to achieve the above object, a fan-out wafer level packaging (FOWLP) unit according to the present invention includes a substrate, at least one die, a first dielectric layer, at least one conductive pillar, a second dielectric layer, a plurality of first conductive circuits, a first outer protective layer, a third dielectric layer, a plurality of second conductive circuits, and a second outer protective layer. The substrate is provided with a first surface, a second surface opposite to the first surface, and at least one first insertion hole penetrating the first surface and the second surface. The die is cut from a wafer and provided with a first surface and a second surface opposite to the each other. The first surface of the die is fixed on the second surface of the substrate while the second surface of the die is provided with a plurality of die pads. A range perpendicular to the second surface of the die is defined as a chip area. The first dielectric layer is mounted to the second surface of the substrate and covering the die. The first dielectric layer is provided with at least one first slot extending horizontally and at least one second insertion hole communicating with the first insertion hole. The conductive pillar is formed in both the first insertion hole and the second insertion hole and exposed through the first insertion hole and the second insertion hole. The second dielectric layer is disposed over the first dielectric layer and provided with a plurality of second slots extending horizontally. The first slot is exposed through the second slot correspondingly. The conductive pillars are exposed through the corresponding second slots. The respective first conductive circuits are formed by a metal paste filled in the respective first slots and the respective second slots and electrically connected with the die pads of the die and the conductive pillar. The first outer protective layer is mounted over the second dielectric layer and the respective first conductive circuits and provided with a plurality of first openings. At least one of the first openings is located around the chip area on the second surface of the die. The respective first conductive circuits are exposed through the respective first openings to form a first bonding pad in each of the first openings. The third dielectric layer is arranged over the first surface of the substrate and provided with a plurality of third slots which is extending horizontally and communicating with the first insertion holes. The respective second conductive circuits are formed by a metal paste filled in the respective third slots and electrically connected with the respective conductive pillars. As to the second outer protective layer, it is mounted over the third dielectric layer and provided with a plurality of second openings. The respective second conductive circuits are exposed through the respective second openings to form a second bonding pad in each of the second openings. The die is electrically connected to the outside through the die pads, the first conductive circuits, and the first bonding pads located around the chip area on the second surface of the die in turn. Thereby the FOWLP unit is formed. The die is further electrically connected to the outside through the die pads, the first conductive circuits, the conductive pillars, the second conductive circuits, and the second bonding pads in turn. A method of manufacturing the FOWLP unit includes the following steps. Step S1: providing a substrate. The substrate includes a first surface and a second surface opposite to each other. Step S2: arranging a plurality of dies cut from at least one wafer at the second surface of the substrate with an interval between the two adjacent dies. Each of the dies includes a first surface and a second surface opposite to the first surface. The first surface of the die is fixed on the second surface of the substrate and the second surface of the die is provided with a plurality of die pads. A range perpendicular to the second surface of the die is defined as a chip area. Step S3: producing a plurality of first conductive circuits on the second surface of the die by filling a metal paste into slots and grinding the metal paste. First paving a first dielectric layer over the second surface of the substrate and the respective dies. Then forming a plurality of first slots horizontally on the first dielectric layer, a plurality of first insertion holes penetrating the substrate, and a plurality of second insertion holes penetrating the first dielectric layer. And exposing the die pads of the dies through the first slots and communicating the first insertion holes with the second insertion holes. Next forming a conductive pillar in the first insertion hole and the second insertion hole communicating with each other. Then covering the first dielectric layer with a second dielectric layer and forming a plurality of second slots horizontally on the second dielectric layer. Later filling a metal paste into the first slots and the second slots and a level of the metal paste is higher than a surface of the second dielectric layer. Last grinding the metal paste with the level higher than the surface of the second dielectric layer to make a surface of the metal paste flush with the surface of the second dielectric layer and form a plurality of the first conductive circuits. Step S4: covering the second dielectric layer with a first outer protective layer. Step S5: forming a plurality of first openings on the first outer protective layer and allowing at least one of the first openings to be located around the chip area on the second surface of the die so that the respective first conductive circuits are exposed through the respective first openings to form a first bonding pad in each of the first openings. Step S:6 producing a plurality of second conductive circuits on the first surface of the substrate by filling a metal paste into slots and grinding the metal paste. First paving a third dielectric layer over the first surface of the substrate. Then forming a plurality of third slots horizontally on the third dielectric layer and exposing the conductive pillar in the first insertion hole through the corresponding third slot. Later filling a metal paste into the third slots and a level of the metal paste is higher than a surface of the third dielectric layer. Last grinding the metal paste with the level higher than the surface of the third dielectric layer to make a surface of the metal paste flush with the surface of the third dielectric layer and form a plurality of the second conductive circuits. Step S7: covering the third dielectric layer with a second outer protective layer. Step S8: forming a plurality of second openings on the second outer protective layer and allowing the respective second conductive circuits to be exposed through the respective second openings to form a second bonding pad in each of the second openings. Step S9: performing cutting to form a plurality of the FOWLP units.

Preferably, the substrate includes silicon (Si) substrate, glass substrate, and ceramic substrate.

Preferably, the metal pastes which form the first conductive circuits and the second conductive circuits include silver paste, nano-scale silver paste, copper paste, and nano-scale copper paste.

Preferably, the first surface of the die is arranged at the substrate by a die attach film (DAF).

Preferably, each of the first openings is provided with a solder ball which is electrically connected with the first bonding pad in the first opening.

Preferably, the FOWLP unit is electrically connected and mounted to a printed circuit board (PCB) by the solder balls.

Preferably, each of the second openings is provided with a solder ball which is electrically connected with the second bonding pad in the second opening.

Preferably, the FOWLP unit further includes a plurality of electronic components each of which is electrically connected and mounted to the FOWLP unit by the solder balls.

### BRIEF DESCRIPTION OF THE DRAWINGS

FIG. 1 is a side sectional view of an embodiment of a FOWLP unit according to the present invention;

FIG. 2 is a side sectional view of a substrate and a die according to the present invention;

FIG. 3 is a side sectional view showing a first dielectric layer paved on a substrate of the embodiment in FIG. 2 according to the present invention;

FIG. 4 is a side sectional view showing a first insertion hole and a second insertion hole respectively formed on a substrate and a first dielectric layer of the embodiment in FIG. 3 according to the present invention;

FIG. 5 is a side sectional view showing conductive pillars mounted in the first insertion hole and the second insertion hole of the embodiment in FIG. 4 according to the present invention;

FIG. 6 is a side sectional view showing at least one first slot formed on the first dielectric layer of the embodiment in FIG. 5 according to the present invention;

FIG. 7 is a side sectional view showing a second dielectric layer disposed over the first dielectric layer of the embodiment in FIG. 6 according to the present invention;

FIG. 8 is a side sectional view showing the first slots and second slots filled with a metal paste of the embodiment in FIG. 7 according to the present invention;

FIG. 9 is a side sectional view showing grinding of the metal paste to form a plurality of first conductive circuits of the embodiment in FIG. 8 according to the present invention;

FIG. 10 is a side sectional view showing a first outer protective layer arranged over the first conductive circuits of the embodiment in FIG. 9 according to the present invention;

FIG. 11 is a side sectional view showing a third dielectric layer paved on the substrate of the embodiment in FIG. 10 according to the present invention;

FIG. 12 is a side sectional view showing third slots filled with a metal paste of the embodiment in FIG. 11 according to the present invention;

FIG. 13 is a side sectional view showing grinding of the metal paste to form a plurality of second conductive circuits of the embodiment in FIG. 12 according to the present invention;

FIG. 14 is a side sectional view showing a second outer protective layer arranged over the second conductive circuits of the embodiment in FIG. 13 according to the present invention;

FIG. 15 is a side sectional view showing solder balls disposed on a first opening and a second opening of the embodiment in FIG. 14 according to the present invention;

FIG. 16 is a side sectional view showing an electronic arranged over the solder balls of the embodiment in FIG. 15 according to the present invention.

### DETAILED DESCRIPTION OF THE PREFFERED EMBODIMENT

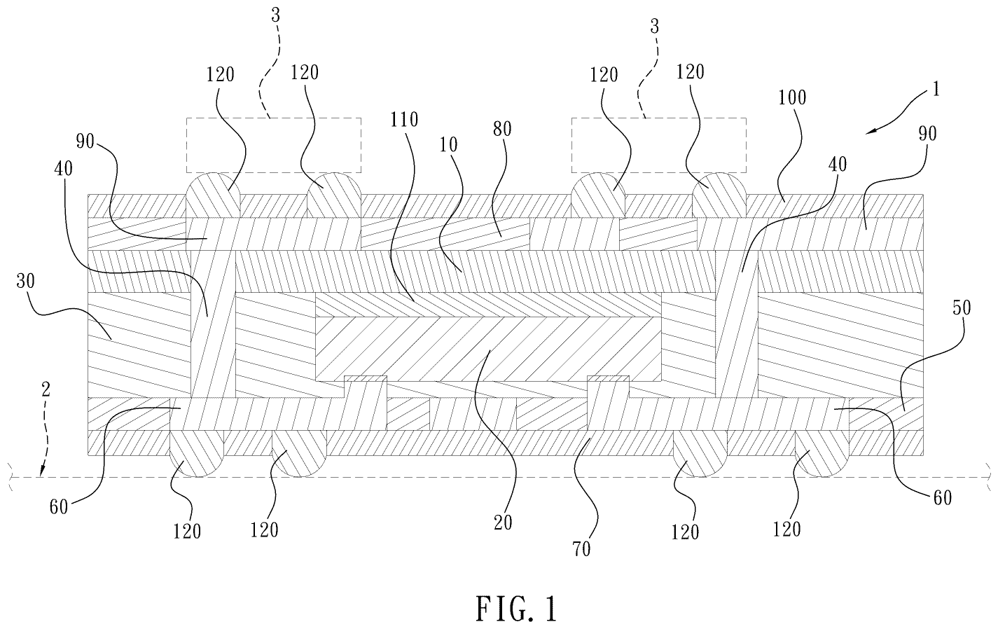

Refer to FIG. 1, a fan-out wafer level packaging (FOWLP) unit 1 according to the present invention includes a substrate 10, at least one die 20, a first dielectric layer 30, at least one conductive pillar 40, a second dielectric layer 50, a plurality of first conductive circuits 60, a first outer protective layer 70, a third dielectric layer 80, a plurality of second conductive circuits 90, and a second outer protective layer 100.

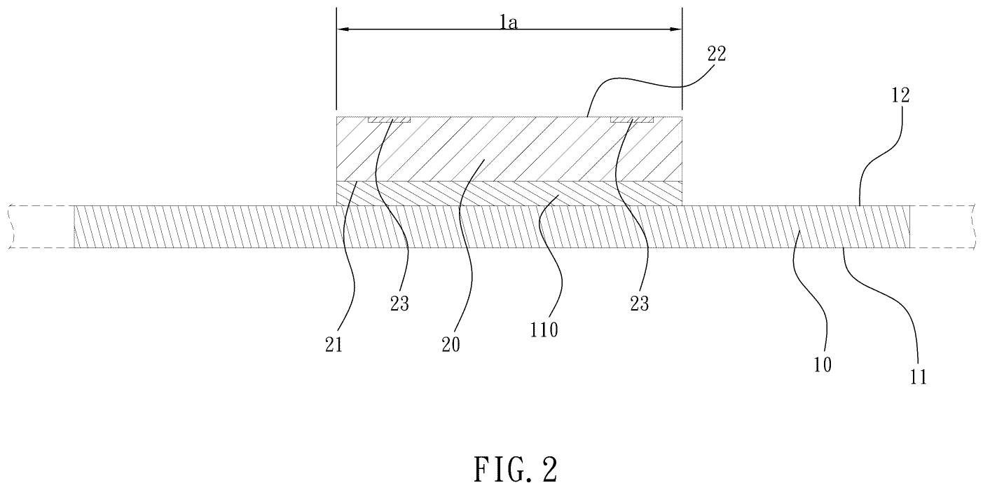

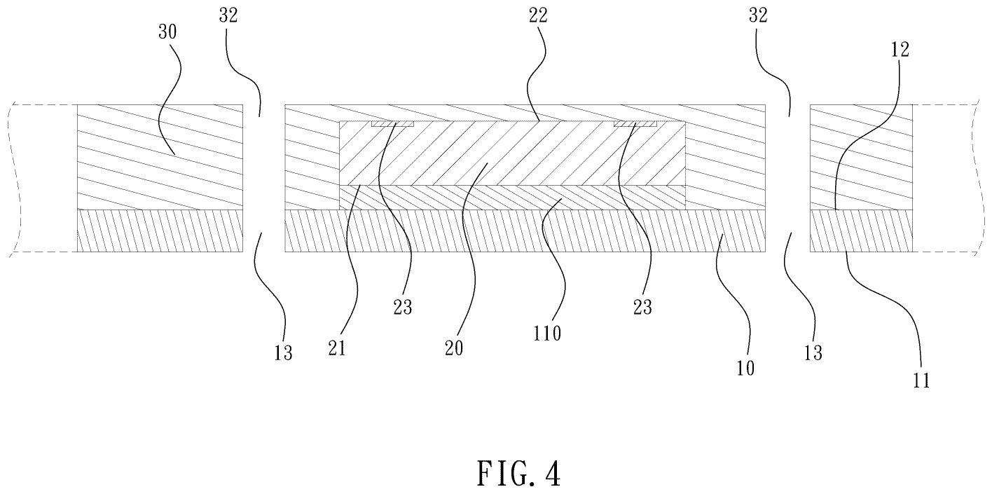

As shown in FIG. 2, the substrate 10 is provided with a first surface 11 and a second surface 12 opposite to the first surface 11. The substrate 10 further includes at least one first insertion hole 13 penetrating the first surface 11 and the second surface 12, as shown in FIG. 4. The substrate 10 includes silicon (Si) substrate, glass substrate, and ceramic substrate.

The die 20 is cut from a wafer and provided with a first surface 21 and a second surface 22 opposite to the first surface 21. The first surface 21 of the die 20 is fixed on the second surface 12 of the substrate 10 while the second surface 22 of the die 20 is provided with a plurality of die pads 23. As shown in FIG. 2, a range perpendicular to the second surface 22 of the die 20 is defined as a chip area 1a.

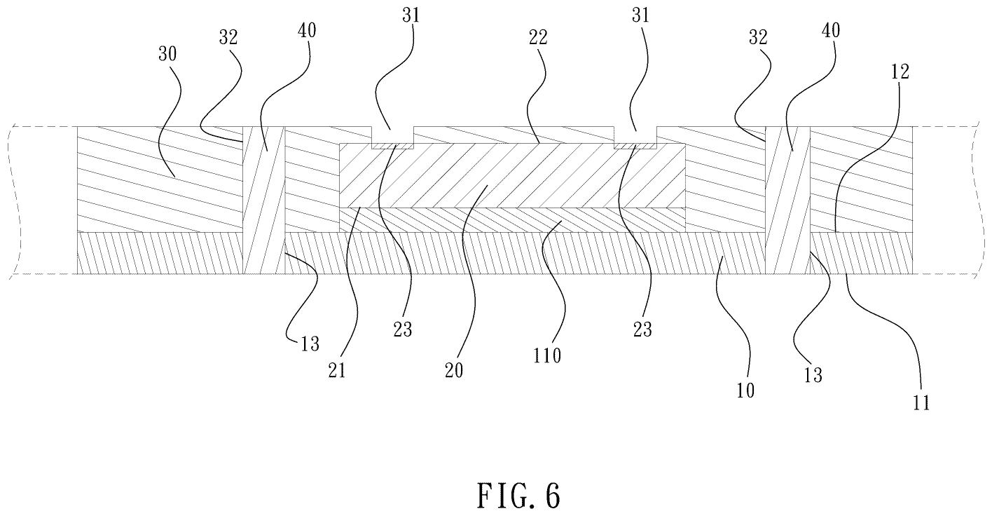

The first dielectric layer 30 is mounted to the second surface 12 of the substrate 10 and covering the die 20. The first dielectric layer 30 is provided with at least one first slot 31 (as shown in FIG. 6) extending in a horizontal direction and at least one second insertion hole 32 (as shown in FIG. 4) communicating with the first insertion hole 13, as shown in FIG. 4. Both the first insertion hole 13 and the second insertion hole 32 are formed by Through Silicon Via (TSV) technique and this helps simplification of the manufacturing process and reduction in packaging thickness.

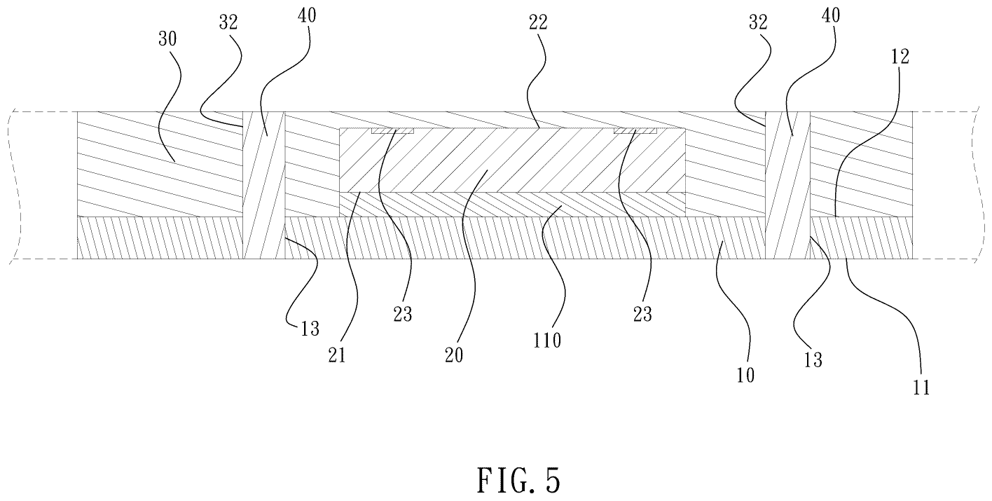

The conductive pillar 40 is formed in both the first insertion hole 13 and the second insertion hole 32 and exposed through the first insertion hole 13 and the second insertion hole 32, as shown in FIG. 5 and FIG. 6.

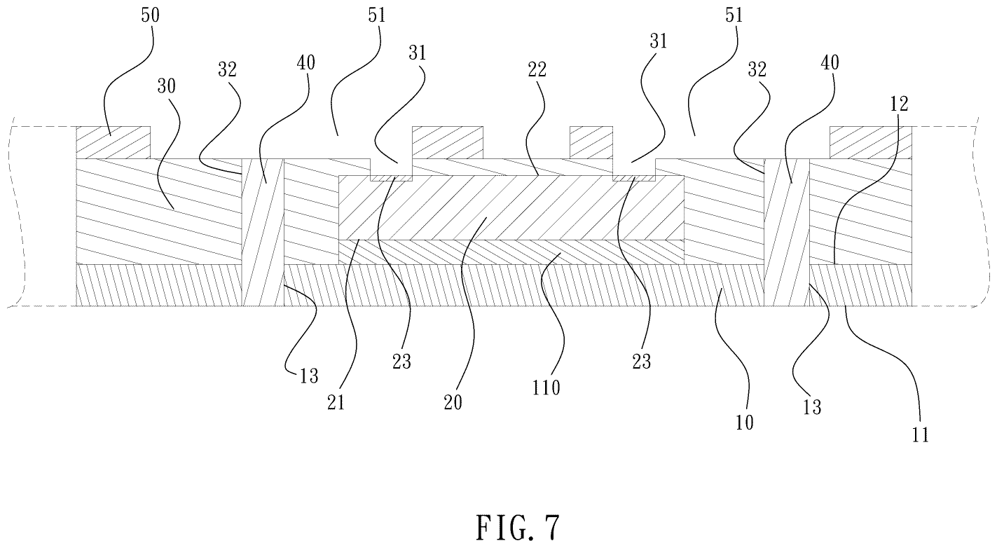

Refer to FIG. 7, the second dielectric layer 50 is disposed over the first dielectric layer 30 and provided with a plurality of second slots 51 extending in a horizontal direction. The first slots 31 are exposed through the second slots 51 correspondingly. The respective conductive pillars 40 are exposed through the corresponding second slots 51, as shown in FIG. 7.

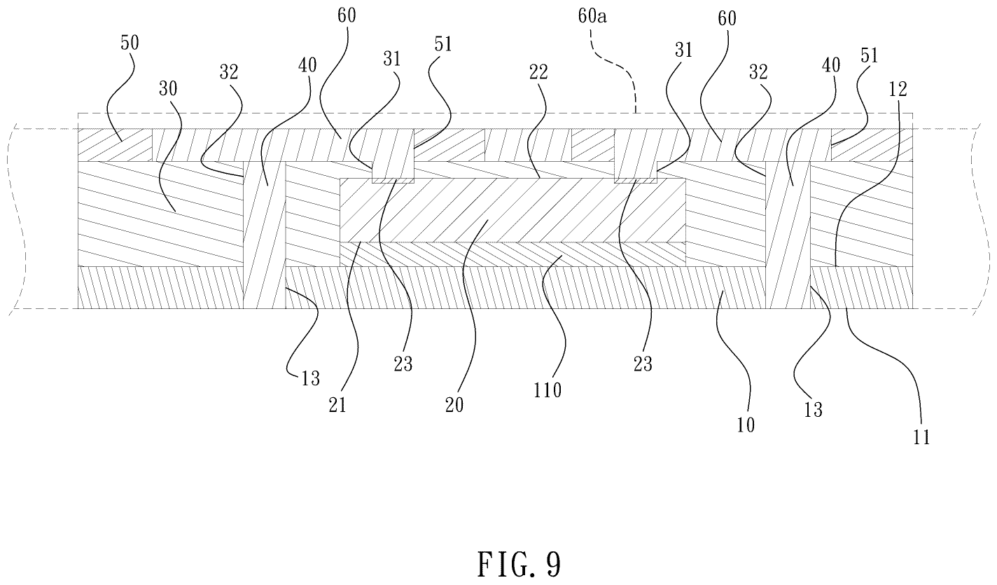

The respective first conductive circuits 60 are formed by a metal paste 60a filled in the respective first slots 31 and the respective second slots 51 and electrically connected with the die pads 23 of the die 20, as shown in FIG. 9.

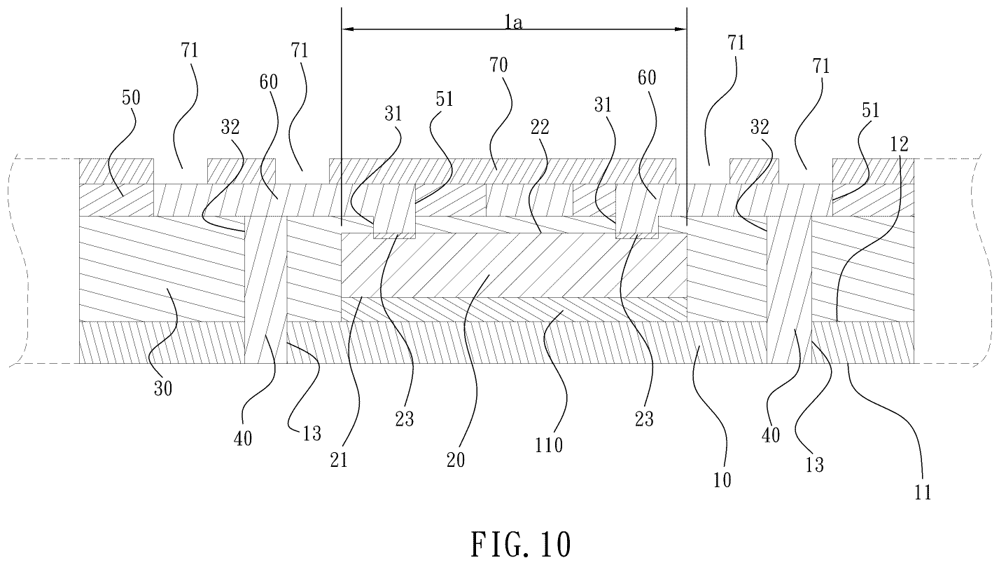

The first outer protective layer 70 is mounted over the second dielectric layer 50 and the first conductive circuits 60 and having a plurality of first openings 71. At least one of the first openings 71 is located around the chip area la on the second surface 22 of the die 20, as shown in FIG. 10. The respective first conductive circuits 60 are exposed through the respective first openings 71 to form a first bonding pad 61 in each of the first openings 71.

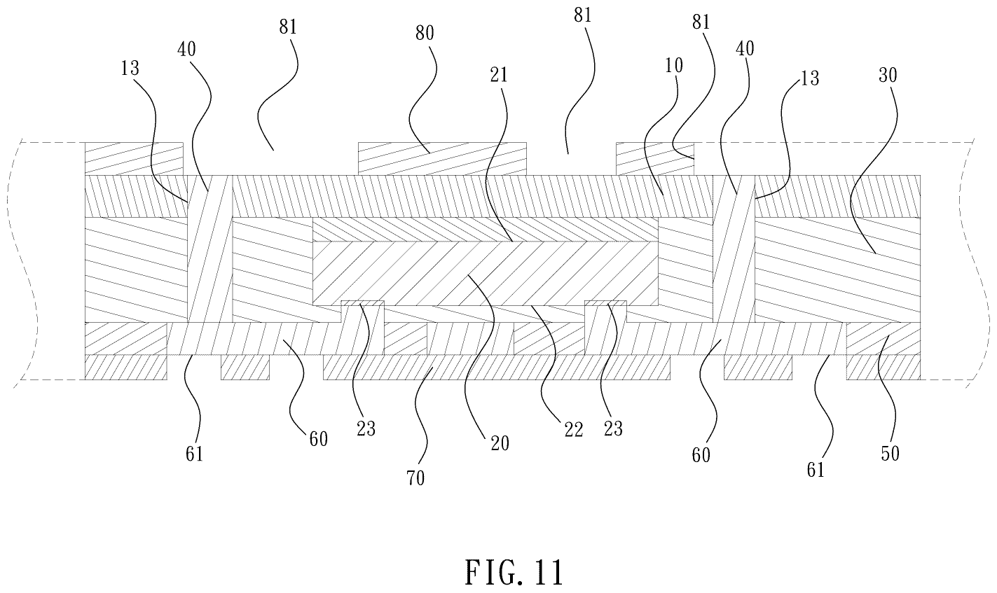

The third dielectric layer 80 is arranged over the first surface 11 of the substrate 10 and provided with a plurality of third slots 81 extending in a horizontal direction. The respective third slots 81 are communicating with the respective first insertion holes 13, as shown in FIG. 11.

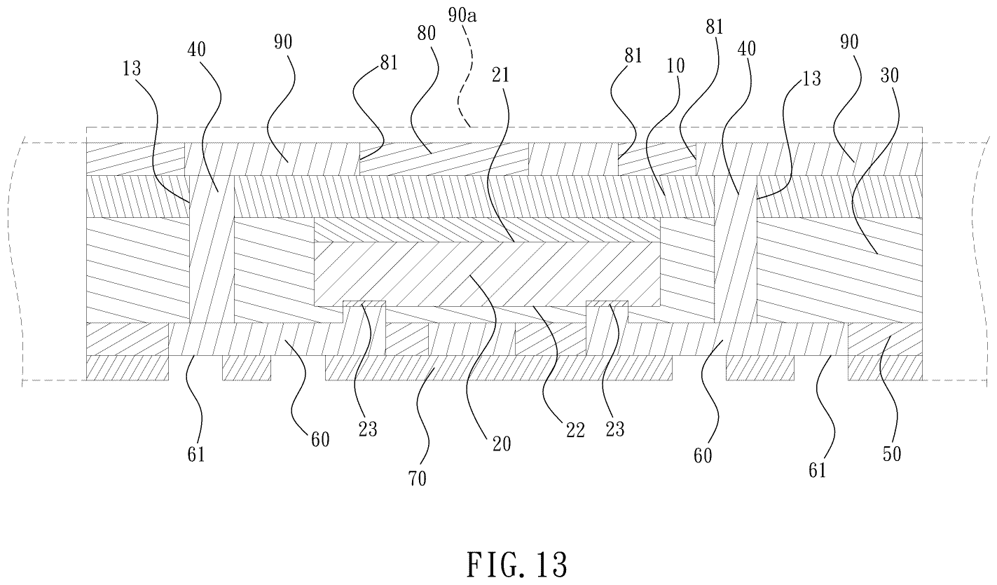

The respective second conductive circuits 90 are formed by a metal paste 90a filled in the respective third slots 81 and electrically connected with the respective conductive pillars 40, as shown in FIG. 13.

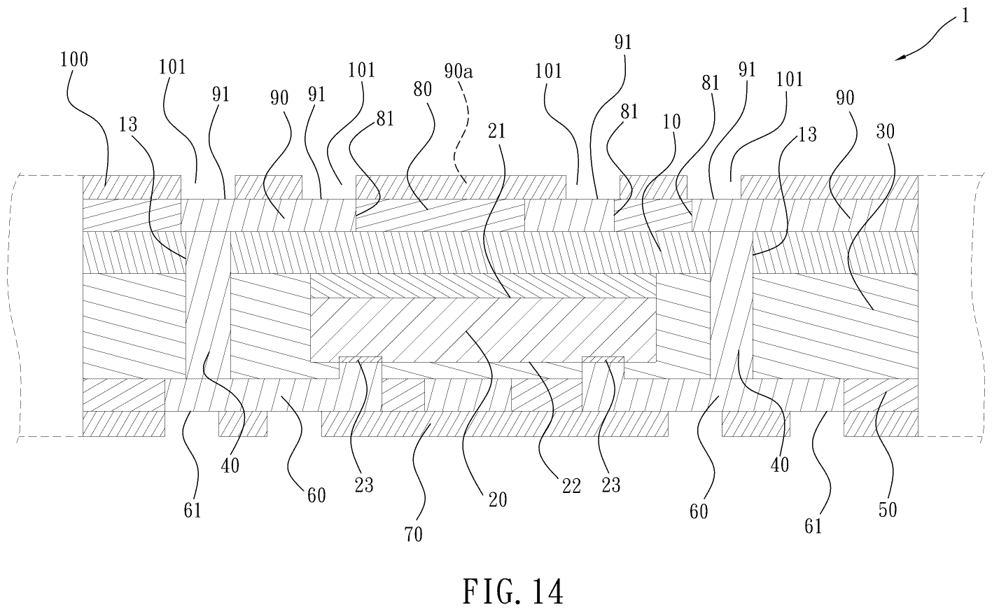

Refer to FIG. 14, the second outer protective layer 100 is mounted over the third dielectric layer 80 and provided with a plurality of second openings 101. The respective second conductive circuits 90 are exposed through the respective second openings 101 to form a second bonding pad 91 in each of the second openings 101.

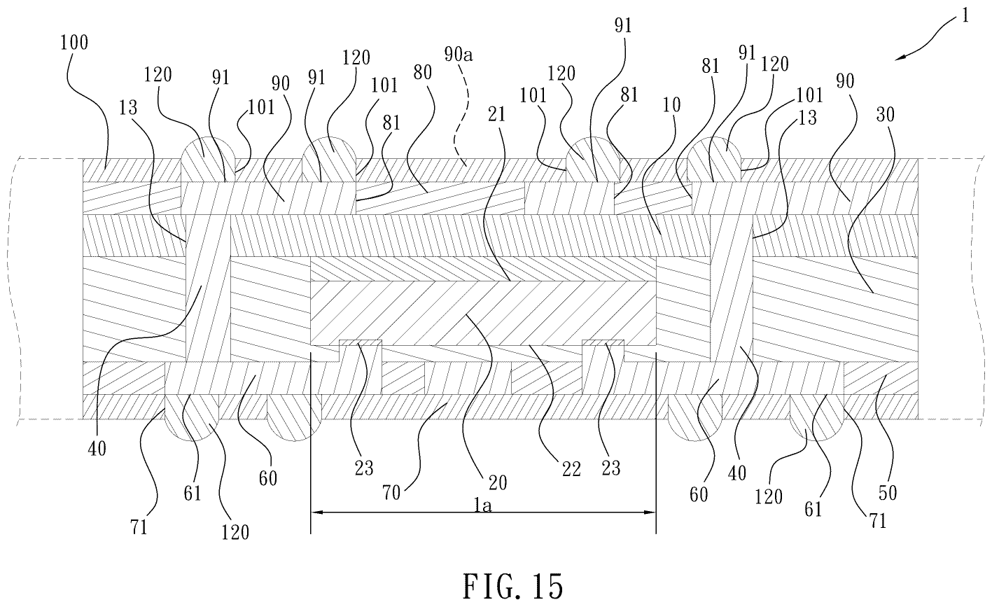

The die 20 is electrically connected to the outside through the die pads 23, the first conductive circuits 60, and the first bonding pads 61 located around the chip area 1a on the second surface 22 of the die 20 in turn. Thereby the FOWLP unit 1 is formed, as shown in FIG. 15. Therefore, the die 20 can be electrically connected to the outside through the die pads 23, the first conductive circuits 60, the conductive pillars 40, the second conductive circuits 90, and the second bonding pads 91 in turn.

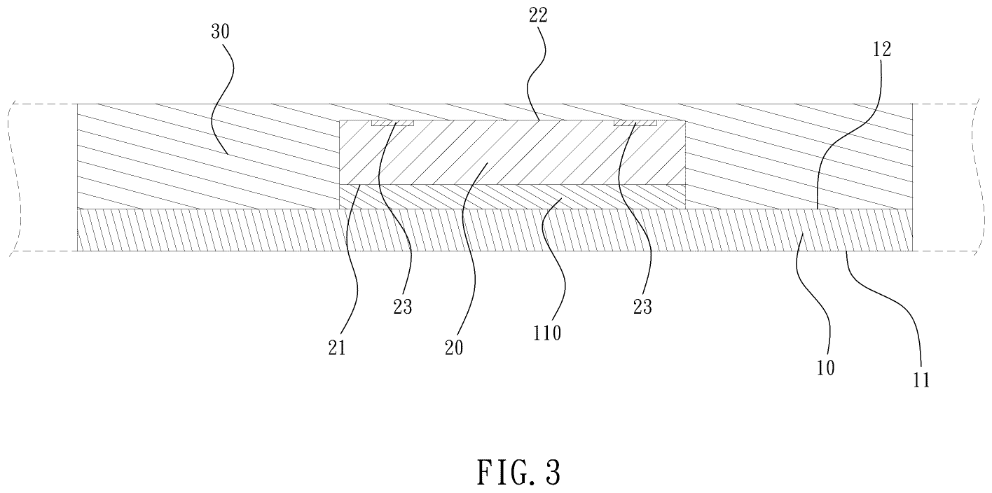

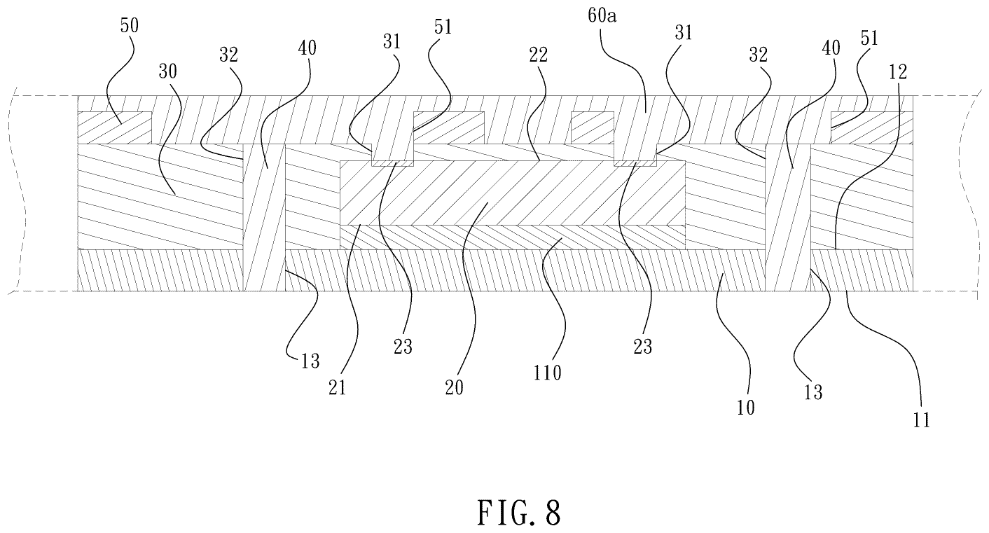

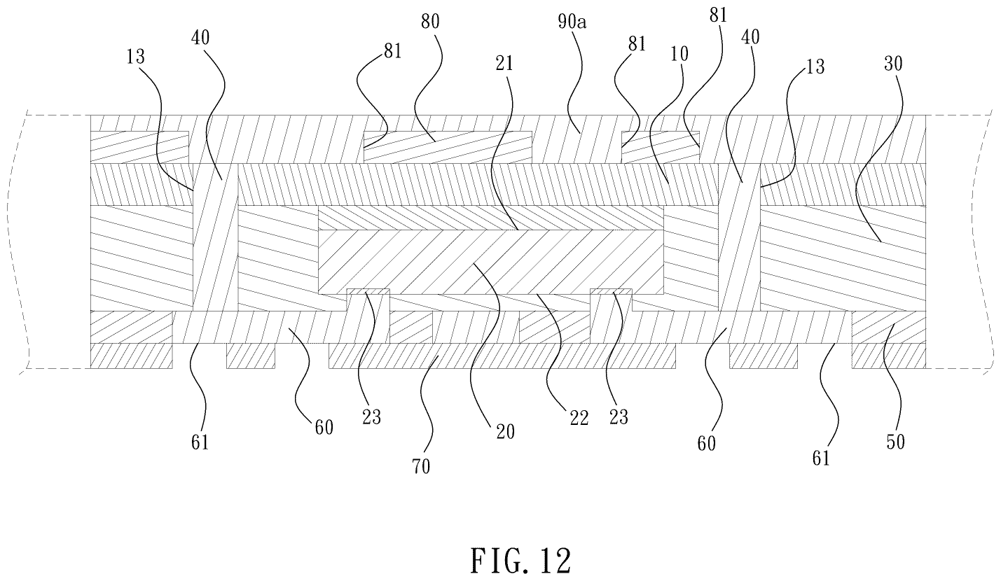

A method of manufacturing the FOWLP unit 1 includes the following steps
Step S1: providing a substrate 10, as shown in FIG. 2. The substrate 10 includes a first surface 11 and a second surface 12 opposite to each other.
Step S2: arranging a plurality of dies 20 cut from at least one wafer on the second surface 12 of the substrate 10 with an interval between the two adjacent dies 20. Each of the dies 20 includes a first surface 21 and a second surface 22 opposite to the first surface 21. The first surface 21 of the die 20 is fixed on the second surface 12 of the substrate 10 and the second surface 22 of the die 20 is provided with a plurality of die pads 23. A range perpendicular to the second surface 22 of the die 20 is defined as a chip area 1a.
Step S3: producing a plurality of first conductive circuits 60 on the) second surface 22 of the die 20 by filling a metal paste into slots and grinding the metal paste. First paving a first dielectric layer 30 over the second surface 12 of the substrate 10 and the respective dies 20, as shown in FIG. 3. Then forming a plurality of first slots 31 (as shown in FIG. 6) horizontally on the first dielectric layer 30, a plurality of first insertion holes 13 penetrating the substrate 10, and a plurality of second insertion holes 32 penetrating the first dielectric layer 30 (as shown in FIG. 4). And exposing the die pads 23 of the dies 20 through the first slots 31 (as shown in FIG. 6) and communicating the first insertion holes 13 with the second insertion holes 32 (as shown in FIG. 4). Next forming a conductive pillar 40 in the first insertion hole 13 and the second insertion hole 32 communicating with each other, as shown in FIG. 5. As shown in FIG. 7, then covering the first dielectric layer 30 with a second dielectric layer 50 and forming a plurality of second slots 51 horizontally on the second dielectric layer 50. Later filling a metal paste 60a into the first slots 31 and the second slots 51 and a level of the metal paste 60a is higher than a surface of the second dielectric layer 50, as shown in FIG. 8. Last grinding the metal paste 60a with the level higher than the surface of the second dielectric layer 50 to make a surface of the metal paste 60a flush with the surface of the second dielectric layer 50 and form a plurality of the first conductive circuits 60, as shown in FIG. 9.
Step S4: covering the second dielectric layer 50 with a first outer protective layer 70, as shown in FIG. 10.
Step S5: forming a plurality of first openings 71 on the first outer protective layer 70 and allowing at least one of the first openings 71 to be located around the chip area la on the second surface 22 of the die 20 so that the respective first conductive circuits 60 are exposed through the respective first openings 71 to form a first bonding pad 61 in each of the first openings 71, as shown in FIG. 10.
Step S:6 producing a plurality of second conductive circuits 90 on the first surface 11 of the substrate 10 by filling a metal paste into slots and grinding the metal paste. First paving a third dielectric layer 80 over the first surface 11 of the substrate 10, as shown in FIG. 11. Then forming a plurality of third slots 81 horizontally on the third dielectric layer 80 and exposing the conductive pillar 40 in the first insertion hole 13 through the corresponding third slot 81, as shown in FIG. 11. Later filling a metal paste 90a into the third slots 81 and a level of the metal paste 90a is higher than a surface of the third dielectric layer 80, as shown in FIG. 12. Last grinding the metal paste 90a with the level higher than the surface of the third dielectric layer 80 to make a surface of the metal paste 90a flush with the surface of the third dielectric layer 80 and form a plurality of the second conductive circuits 90, as shown in FIG. 13.
Step S7: covering the third dielectric layer 80 with a second outer protective layer 100, as shown in FIG. 14;
Step S8: forming a plurality of second openings 101 on the second outer protective layer 100 and allowing the respective second conductive circuits 90 to be exposed through the respective second openings 101 to form a second bonding pad 91 in each of the second openings 101, as shown in FIG. 14.
Step S9: performing cutting to form a plurality of the FOWLP units 1, as shown in FIG. 1.

Refer to FIG. 9 and FIG. 13, the metal pastes 60a, 90a which form the first conductive circuits 60 and the second conductive circuits 90) correspondingly include silver paste, nano-scale silver paste, copper paste, and nano-scale copper paste. The nano-scale silver paste has features of low cost, high conductivity, and low-temperature sintering.

Refer to FIG. 2, the first surface 21 of the die 20 is arranged at the substrate 10 by a die attach film (DAF) 110.

Refer to FIG. 15, each of the first openings 71 is provided with a solder ball 120 which is electrically connected with the first bonding pad 61 inside the first opening 71.

Refer to FIG. 1, the FOWLP unit 1 is electrically connected and mounted to a printed circuit board (PCB) 2 by the solder balls 120.

Refer to FIG. 15, each of the second openings 101 is provided with a solder ball 120 which is electrically connected with the second bonding pad 91 inside the second opening 101.

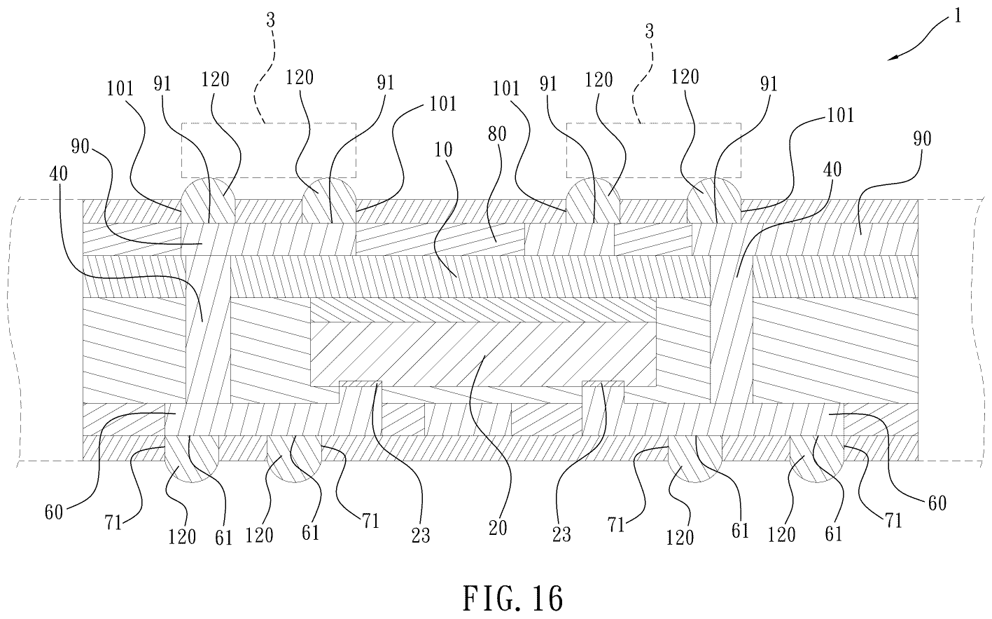

Refer to FIG. 1 and FIG. 16, the FOWLP unit 1 includes a plurality of electronic components 3 each of which is electrically connected and mounted to the FOWLP unit 1 by the solder balls 120.

Compared with the FOWLP unit available now, the present FOWLP unit 1 has the following advantages.
(1) The steps S3 and S6 of the present method of manufacturing the FOWLP unit 1 are considered as key steps in production of RDL of the FOWLP unit. The steps S3 and S6 are precise and easily-implemented steps. Thus the manufacturing process is simplified so that a more compact design is achieved under condition that conductive circuits in the RDL make a plurality of die pads on dies have electrical extension in the XY plane and interconnections. This especially helps in reduction of the thickness of the FOWLP unit 1. Thus not only production cost is reduced, use efficiency and reliability of the FOWLP unit 1 are improved effectively.
(2) The first conductive circuits 60 and the second conductive circuits 90 of the present invention are formed by filling metal paste into the slots and then grinding the metal paste. Thus the problems of the FOWLP technology available now generated during manufacturing of the respective conductive circuits including higher manufacturing cost and less environmental benefit can be solved effectively by the present invention.
(3) By the conductive pillars 40 inside the FOWLP unit 1, the respective dies 20 in the FOWLP unit 1 are electrically connected to the outside through the two opposite surfaces of the FOWLP unit 1. Without increasing the whole thickness, the dies in the FOWLP unit can be electrically connected to the outside through the two opposite surfaces of the packaging unit. Thereby the requirements for lightweight and small-sized electronics are satisfied.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A fan-out wafer level packaging (FOWLP) unit comprising:
a substrate provided with a first surface and a second surface opposite to the first surface; wherein the substrate includes at least one first insertion hole penetrating the first surface and the second surface;
at least one die cut from a wafer and provided with a first surface and a second surface opposite to the each other; the first surface of the die fixed on the second surface of the substrate while the second surface of the die provided with a plurality of die pads; a range perpendicular to the second surface of the die being defined as a chip area;
a first dielectric layer mounted to the second surface of the substrate and covering the die; the first dielectric layer provided with at least one first slot extending horizontally and at least one second insertion hole; wherein the second insertion hole is communicating with the first insertion hole;
at least one conductive pillar formed in both the first insertion hole and the second insertion hole and exposed through the first insertion hole and the second insertion hole;
a second dielectric layer disposed over the first dielectric layer and provided with a plurality of second slots extending horizontally; wherein the first slot is exposed through the second slot correspondingly; wherein the conductive pillar is exposed through the second slot correspondingly;
a plurality of first conductive circuits formed by a metal paste filled in the first slots and the second slots; the first conductive circuits electrically connected with the die pads of the die and the conductive pillar;
a first outer protective layer mounted over the second dielectric layer and the first conductive circuits and provided with a plurality of first openings; at least one of the first openings located around the chip area on the second surface of the die; wherein the respective first conductive circuits are exposed through the respective first openings to form a first bonding pad in each of the first openings;
a third dielectric layer arranged over the first surface of the substrate and provided with a plurality of third slots which is extending horizontally and communicating with the first insertion holes;
a plurality of second conductive circuits formed by a metal paste filled in the respective third slots and electrically connected with the conductive pillar;
a second outer protective layer mounted over the third dielectric layer and provided with a plurality of second openings; wherein the respective second conductive circuits are exposed through the respective second openings to form a second bonding pad in each of the second openings;
wherein the die is electrically connected to the outside through the die pads, the first conductive circuits, and the first bonding pads located around the chip area on the second surface of the die in turn; thereby the FOWLP unit is formed;
wherein the die is further electrically connected to the outside through the die pads, the first conductive circuits, the conductive pillar, the second conductive circuits, and the second bonding pads in turn;
wherein a method of manufacturing the FOWLP unit comprising the steps of:
Step S1: providing a substrate; wherein the substrate includes a first surface and a second surface opposite to the first surface;
Step S2: arranging a plurality of dies cut from at least one wafer at the second surface of the substrate with an interval between the two adjacent dies; wherein each of the dies includes a first surface and a second surface opposite to the first surface; the first surface of the die is fixed on the second surface of the substrate and the second surface of the die is provided with a plurality of die pads; a range perpendicular to the second surface of the die is defined as a chip area;
Step S3: producing a plurality of first conductive circuits on the second surface of the die by filling a metal paste into slots and grinding the metal paste; first paving a first dielectric layer over the second surface of the substrate and the respective dies; then forming a plurality of first slots horizontally on the first dielectric layer, a plurality of first insertion holes penetrating the substrate, and a plurality of second insertion holes penetrating the first dielectric layer; and exposing the die pads of the dies through the first slots and communicating the first insertion holes with the second insertion holes; next forming a conductive pillar in the first insertion hole and the second insertion hole communicating with each other; then covering the first dielectric layer with a second dielectric layer and forming a plurality of second slots horizontally on the second dielectric layer; later filling a metal paste into the first slots and the second slots and a level of the metal paste is higher than a surface of the second dielectric layer; lastly grinding the metal paste with the level higher than the surface of the second dielectric layer to make a surface of the metal paste flush with the surface of the second dielectric layer and form a plurality of the first conductive circuits;
Step S4: covering the second dielectric layer with a first outer protective layer;
Step S5: forming a plurality of first openings on the first outer protective layer and allowing at least one of the first openings to be located around the chip area on the second surface of the die so that the respective first conductive circuits are exposed through the respective first openings to form a first bonding pad in each of the first openings;
Step S:6 producing a plurality of second conductive circuits on the first surface of the substrate by filling a metal paste into slots and grinding the metal paste; first paving a third dielectric layer over the first surface of the substrate; then forming a plurality of third slots horizontally on the third dielectric layer and exposing the conductive pillar in the first insertion hole through the corresponding third slot; later filling a metal paste into the third slots and allowing a level of the metal paste higher than a surface of the third dielectric layer; lastly grinding the metal paste with the level higher than the surface of the third dielectric layer to make a surface of the metal paste flush with the surface of the third dielectric layer and form a plurality of the second conductive circuits;
Step S7: covering the third dielectric layer with a second outer protective layer;
Step S8: forming a plurality of second openings on the second outer protective layer and allowing the respective second conductive circuits to be exposed through the respective second openings to form a second bonding pad in each of the second openings; and
Step S9: performing cutting to form a plurality of the FOWLP units.

2. The FOWLP unit as claimed in claim 1, wherein the substrate includes silicon (Si) substrate, glass substrate, and ceramic substrate.

3. The FOWLP unit as claimed in claim 1, wherein the metal paste which forms the first conductive circuits includes silver paste, nano-scale silver paste, copper paste, and nano-scale copper paste.

4. The FOWLP unit as claimed in claim 1, wherein the metal paste which forms the second conductive circuits includes silver paste, nano-scale silver paste, copper paste, and nano-scale copper paste.

5. The FOWLP unit as claimed in claim 1, wherein the first surface of the) die is arranged at the substrate by a die attach film (DAF).

6. The FOWLP unit as claimed in claim 1, wherein each of the first openings is provided with a solder ball which is electrically connected with the first bonding pad in the first opening.

7. The FOWLP unit as claimed in claim 6, wherein the FOWLP unit is electrically connected and mounted to a printed circuit board (PCB) by the solder balls.

8. The FOWLP unit as claimed in claim 1, wherein each of the second openings is provided with a solder ball which is electrically connected with the second bonding pad in the second opening.

9. The FOWLP unit as claimed in claim 8, wherein the FOWLP unit further includes a plurality of electronic components each of which is electrically connected and mounted to the FOWLP unit by the solder balls.
